(19) United States
(12) Patent Application Publication
(10) Pub. No.: US 2025/0031582 A1
(43) Pub. Date: Jan. 23, 2025

(54) MAGNETOELECTRIC CONVERSION ELEMENT AND MANUFACTURING METHOD OF MAGNETOELECTRIC CONVERSION ELEMENT

(71) Applicant: ROHM Co., LTD., Kyoto (JP)

(72) Inventors: Daiju Takamizu, Kyoto (JP); Satoshi Nakagawa, Kyoto (JP)

(21) Appl. No.: 18/777,735

(22) Filed: Jul. 19, 2024

(30) Foreign Application Priority Data
Jul. 19, 2023 (JP) 2023-117396

(51) Int. Cl. H10N 52/80; H10N 52/00; H10N 52/01

(52) U.S. Cl. CPC H10N 52/80; H10N 52/01; H10N 52/101

(57) ABSTRACT

Provided is a magnetoelectric conversion element including a substrate including a compound semiconductor, a magnetic sensitive layer formed in a predetermined pattern on a top surface of the substrate, a selective growth mask layer formed on the top surface to cover the magnetic sensitive layer such that the magnetic sensitive layer is exposed in a predetermined pattern, a contact layer formed on the magnetic sensitive layer exposed from the selective growth mask layer, a contact resistance to metal of the contact layer being lower than a contact resistance to metal of the magnetic sensitive layer, and a metal electrode layer formed in a predetermined pattern on the selective growth mask layer and the contact layer in such a manner as to cover at least the contact layer, in which each of the magnetic sensitive layer and the contact layer includes the compound semiconductor.

### CROSS REFERENCE TO RELATED APPLICATIONS

This application claims priority benefit of Japanese Patent Application No. JP 2023-117396 filed in the Japan Patent Office on Jul. 19, 2023. Each of the above-referenced applications is hereby incorporated herein by reference in its entirety.

### BACKGROUND

The present disclosure relates to a magnetoelectric conversion element and a manufacturing method of the magnetoelectric conversion element.

A Hall element is known as an example of a magnetoelectric conversion element. The Hall element is configured to convert a magnetic signal into an electrical signal and detect the signal. The Hall element is used in a wide range of fields, such as a current sensor and a rotation angle detection sensor of a motor. The configuration of the Hall element in the past is disclosed in, for example, Japanese Patent Laid-Open No. 2017-50394. The Hall element disclosed in Japanese Patent Laid-Open No. 2017-50394 includes a magnetic sensitive layer including an n-type semiconductor containing GaAs (gallium arsenide) doped with Si (silicon) as impurities, in which the magnetic sensitive layer is formed in a cross shape in plan view on a substrate.

### BRIEF DESCRIPTION OF THE DRAWINGS

FIG. 1 is a plan view of a Hall element of a first embodiment;

FIG. 2 is a cross-sectional view of the Hall element of the first embodiment;

FIG. 3A is a cross-sectional view illustrating a series of processes in a manufacturing method of the Hall element of the first embodiment;

FIG. 3B is a cross-sectional view illustrating the series of processes in the manufacturing method of the Hall element of the first embodiment;

FIG. 3C is a cross-sectional view illustrating the series of processes in the manufacturing method of the Hall element of the first embodiment;

FIG. 3D is a cross-sectional view illustrating the series of processes in the manufacturing method of the Hall element of the first embodiment;

FIG. 3E is a cross-sectional view illustrating the series of processes in the manufacturing method of the Hall element of the first embodiment;

FIG. 3F is a cross-sectional view illustrating the series of processes in the manufacturing method of the Hall element of the first embodiment;

FIG. 3G is a cross-sectional view illustrating the series of processes in the manufacturing method of the Hall element of the first embodiment;

FIG. 4A is a partially enlarged cross-sectional view of the Hall element of a first modification;

FIG. 4B is a partially enlarged cross-sectional view of the Hall element of a second modification;

FIG. 5 is a cross-sectional view of a Hall element of a second embodiment; and

FIG. 6 is a cross-sectional view of a Hall element of a third embodiment.

### DETAILED DESCRIPTION

Embodiments of a magnetoelectric conversion element and a manufacturing method of the magnetoelectric conversion element will be described in detail with reference to the drawings. A Hall element will be described as an example of the magnetoelectric conversion element in the embodiments.

### First Embodiment

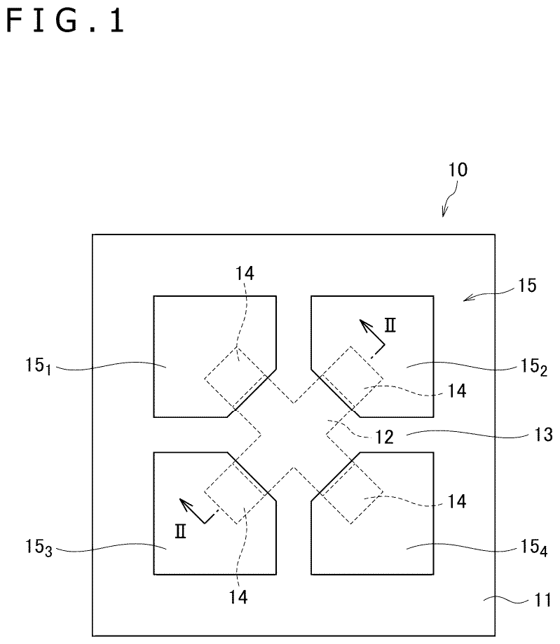

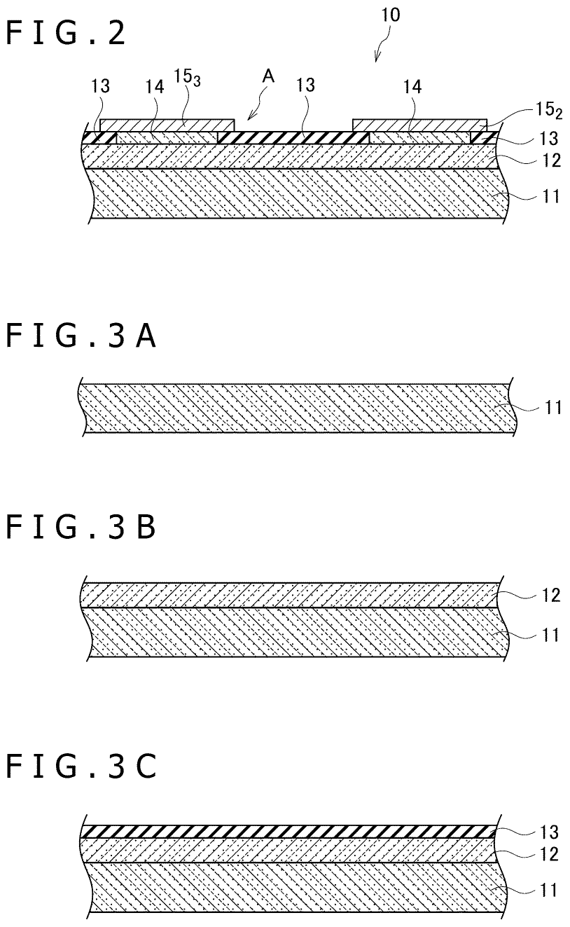

FIG. 1 is a plan view illustrating a Hall element 10 of a first embodiment. FIG. 2 is a cross-sectional view of the Hall element 10 cut along a cutting line II-II in FIG. 1.

The Hall element 10 includes a substrate 11, and a magnetic sensitive layer 12, a selective growth mask layer 13, a contact layer 14, and metal electrode layers 15 sequentially laminated on a top surface of the substrate 11. The selective growth mask layer 13 and the contact layer 14 are arranged in the same layer to form one layer.

The magnetic sensitive layer 12 is formed on the top surface of the substrate 11 substantially rectangular in plan view, and the magnetic sensitive layer 12 is formed in a substantially cross-shaped pattern in plan view extending in two diagonal directions of the substantially rectangular substrate 11. The selective growth mask layer 13 and the contact layer 14 forming one layer are further formed on the top surface of the substrate 11 in such a manner as to cover the magnetic sensitive layer 12. Predetermined areas of this layer covering ends of the magnetic sensitive layer 12 formed in the substantially cross-shaped pattern are formed by the contact layer 14, and the rest of the layer is formed by the selective growth mask layer 13. The contact layer 14 is formed just below the electrically separated metal electrode layers 15 and is covered by the metal electrode layers 15. The metal electrode layers 15 are further extended to areas adjacent to the contact layer 14 on the selective growth mask layer 13 and are formed in a predetermined pattern.

The metal electrode layers 15 include four layers including first to fourth metal electrode layers 15₁ to 15₄. Among them, the first metal electrode layer 15₁ and the third metal electrode layer 15₃ facing each other in one diagonal direction are input terminals, and the second metal electrode layer 15₂ and the fourth metal electrode layer 15₄ facing each other in the other diagonal direction are output terminals, for example. In the magnetic sensitive layer 12, Lorentz force acts on a carrier moving in a path between the pair of input terminals, such as the first metal electrode layer 15₁ and the third metal electrode layer 15₃, in a direction orthogonal to the movement direction due to the magnetic field penetrating the magnetic sensitive layer 12. Electromotive force corresponding to the strength of the magnetic field is detected at the output terminals, such as the second metal electrode layer 15₂ and the fourth metal electrode layer 15₄, facing each other in a direction substantially orthogonal to the movement direction.

In the Hall element 10 of the first embodiment, the substrate 11 includes a compound semiconductor containing III-V GaAs. The magnetic sensitive layer 12 includes an n-type compound semiconductor containing GaAs doped with at least one of Si and Te (tellurium) as impurities. To secure the sensitivity of detecting the magnetism, the impurities are added to the magnetic sensitive layer 12 in low concentration so that the mobility of the carrier becomes high.

The selective growth mask layer 13 contains SiO₂ (silicon dioxide). The selective growth mask layer 13 inhibits the crystal growth on the surface of the selective growth mask layer 13 and enables selective crystal growth in areas not covered. The contact layer 14 is formed by the selective growth in the areas not covered by the selective growth mask layer 13. The formation of the contact layer 14 by the selective growth will be further described later.

The contact layer 14 includes an n-type compound semiconductor containing GaAs doped with Te as impurities. The contact layer 14 is placed between the magnetic sensitive layer 12 with a low carrier concentration and the metal electrode layers 15. Te is added to the contact layer 14 in high concentration to reduce the contact resistance between the contact layer 14 and the metal electrode layers 15, and the carrier concentration of the contact layer 14 is high. Although the contact layer 14 is in contact with the magnetic sensitive layer 12, Te in high concentration contained in the contact layer 14 has a property of being likely to be diffused. Therefore, the degradation of the magnetic sensitive layer 12, such as reduction in the mobility caused by the diffusion of Te to the magnetic sensitive layer 12, does not occur, and the sensitivity of the Hall element 10 is secured.

A laminated body including, for example, sequentially laminated AuGe (gold germanium), Ni (nickel), and Au (gold) may be used for the metal electrode layers 15. Although III-V GaAs is used for the compound semiconductor included in the substrate 11, the magnetic sensitive layer 12, and the contact layer 14 in the Hall element 10 of the first embodiment, the compound semiconductor is not limited to this. Other types of compound semiconductors, such as InSb (indium antimonide) and InAs (indium arsenide), may also be used.

In the Hall element 10 of the first embodiment, Te is used as impurities added to the contact layer 14 in high concentration. Therefore, Te in high concentration added to the contact layer 14 can provide the carrier in high concentration to reduce the contact resistance between the contact layer 14 and the metal electrode layers 15 in the first embodiment. The reduction in the contact resistance can improve the sensitivity or the efficiency of the Hall element 10. Te has a property of being likely to be diffused. Therefore, even if the contact layer 14 doped with Te in high concentration is in contact with the magnetic sensitive layer 12, the sensitivity is not reduced by the degradation of the magnetic sensitive layer 12 caused by diffusion of Te.

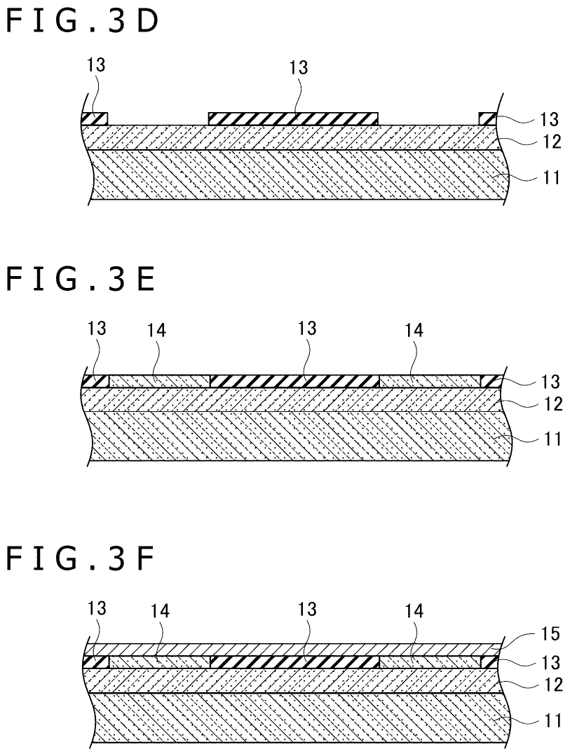

FIGS. 3A to 3G are cross-sectional views illustrating a series of processes of manufacturing the Hall element 10. The manufacturing method of the Hall element 10 will be described with reference to the drawings.

As illustrated in FIG. 3A, the substrate 11 containing GaAs is prepared. As illustrated in FIG. 3B, an n-type compound semiconductor containing GaAs doped with at least one of Si and Te as impurities is deposited on the top surface of the substrate 11 to form the magnetic sensitive layer 12 in a predetermined thickness. To secure the sensitivity of detecting the magnetism, the impurities are added to the magnetic sensitive layer 12 in low concentration so that the mobility of the carrier becomes high. Following the formation of the magnetic sensitive layer 12, unnecessary parts are removed from the magnetic sensitive layer 12 by etching or other methods so that the magnetic sensitive layer 12 forms a substantially cross-shaped pattern in plan view on the top surface of the substrate 11.

As illustrated in FIG. 3C, SiO₂ is deposited on the top surface of the substrate 11 in such a manner as to cover the magnetic sensitive layer 12 formed in the substantially cross-shaped pattern, and the selective growth mask layer 13 is formed in a predetermined thickness. The selective growth mask layer 13 inhibits the crystal growth on the surface of the selective growth mask layer 13 and enables the selective crystal growth in the areas not covered by the selective growth mask layer 13. Following the formation of the selective growth mask layer 13, unnecessary parts are removed from the selective growth mask layer 13 by etching or other methods so that the selective growth mask layer 13 opens in predetermined areas at the ends of the magnetic sensitive layer 12 formed in the substantially cross-shaped pattern and exposes the magnetic sensitive layer 12.

As illustrated in FIG. 3D, the crystal is grown in the contact layer 14 including the n-type compound semiconductor containing GaAs doped with Te as impurities on the surface of the exposed magnetic sensitive layer 12, at the openings of the selective growth mask layer 13 formed in the predetermined areas at the ends of the magnetic sensitive layer 12 with the substantially cross-shaped pattern. Te in high concentration is added to the contact layer 14 to reduce the contact resistance between the contact layer 14 and the metal electrode layers 15, and the carrier concentration of the contact layer 14 is high. The crystal growth is continued in the contact layer 14 from the magnetic sensitive layer 12 exposed in the openings until the contact layer 14 reaches the height of the selective growth mask layer 13 surrounding the openings. As a result of the selective growth, the contact layer 14 is fitted into the predetermined open areas of the selective growth mask layer 13, and one layer including the selective growth mask layer 13 and the contact layer 14 arranged in the same layer is formed.

As illustrated in FIG. 3F, a laminated body containing, for example, sequentially laminated AuGe, Ni, and Au is used to form the metal electrode layers 15 in such a manner as to cover one layer including the selective growth mask layer 13 and the contact layer 14. As illustrated in FIG. 3G, unnecessary parts are removed from the metal electrode layers 15 by etching, lift-off, or other methods. As a result, the metal electrode layers 15 are formed in a predetermined pattern as illustrated in FIG. 1, in which the metal electrode layers 15 cover the contact layer 14 exposed from the selective growth mask layer 13 in the predetermined areas at the ends of the substantially cross-shaped magnetic sensitive layer 12, and the metal electrode layers 15 are further extended to the areas adjacent to the contact layer 14 on the selective growth mask layer 13. In this way, the magnetic sensitive layer 12, the selective growth mask layer 13, the contact layer 14, and the metal electrode layers 15 in the Hall element 10 illustrated in FIGS. 1 and 2 are formed through the series of processes from FIG. 3A to FIG. 3G, and the Hall element 10 as illustrated in FIGS. 1 and 2 is obtained.

Although etching is used for the formation of the substantially cross-shaped pattern of the magnetic sensitive layer 12 in the process illustrated in FIG. 3B, the formation of the openings in the selective growth mask layer 13 in the process illustrated in FIG. 3C, and the formation of the predetermined pattern of the metal electrode layers 15 in the process illustrated in FIG. 3G in the example of the manufacturing method of the Hall element 10 of the first embodiment, the method is not limited to this, and other methods, such as lift-off, may also be used. Although III-V GaAs is used for the compound semiconductor included in the substrate 11, the magnetic sensitive layer 12, and the contact layer 14 in the manufacturing method of the Hall element 10 of the first embodiment, the compound semiconductor is not limited to this, and other types of compound semiconductors, such as InSb and InAs, may also be used.

In the manufacturing method of the first embodiment, the contact layer 14 can be formed by forming the selective growth mask layer 13 in the predetermined pattern on the top surface of the substrate 11 in such a manner as to cover the magnetic sensitive layer 12 in the substantially cross-shaped pattern and selectively growing the crystal on the magnetic sensitive layer 12 exposed in the openings formed on the selective growth mask layer 13. The selective growth mask layer 13 can be used to easily form the contact layer 14 in a desirable pattern and a desirable thickness, at the position on the magnetic sensitive layer 12 just below the metal electrode layers 15. The selective growth mask layer 13 contains SiO₂, and the selective growth mask layer 13 plays a role of protecting the covered top surface of the substrate 11 and the magnetic sensitive layer 12.

In the Hall element 10 created by the manufacturing method of the first embodiment, Te is used as impurities added in high concentration to the contact layer 14. Therefore, Te in high concentration can provide the carrier in high concentration to reduce the contact resistance between the contact layer 14 and the metal electrode layers 15. The reduction in the contact resistance can improve the sensitivity or the efficiency of the Hall element 10. Although the contact layer 14 is in contact with the magnetic sensitive layer 12, Te in high concentration included in the contact layer 14 has a property of being likely to be diffused. Therefore, the degradation of the magnetic sensitive layer 12, such as reduction in the mobility caused by the diffusion of Te to the magnetic sensitive layer 12, does not occur, and the sensitivity of the Hall element 10 is secured.

In the Hall element 10 of the first embodiment, the selective growth mask layer 13 contains SiO₂ that is more excellent in adhesion to GaAs than SiN described later. This secures the adhesion of the selective growth mask layer 13 and the magnetic sensitive layer 12 containing n-type GaAs.

### Modifications

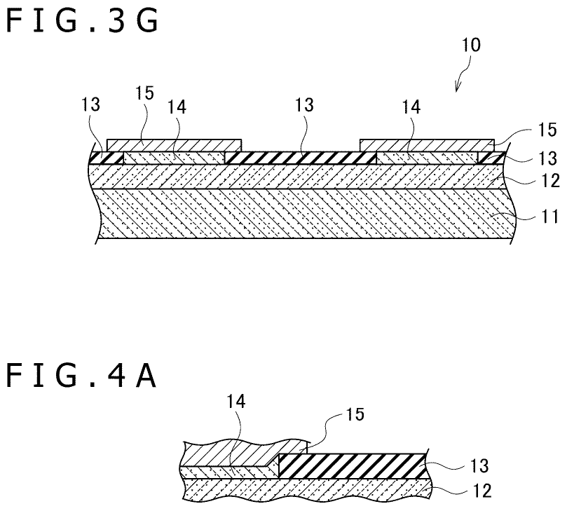

FIGS. 4A and 4B are partially enlarged cross-sectional views of the Hall element 10 of modifications. The part indicated by an arrow A in the cross-sectional view of FIG. 2 is enlarged in FIGS. 4A and 4B. The contact layer 14 is thinner than the selective growth mask layer 13 in the Hall element 10 of a first modification illustrated in FIG. 4A. The contact layer 14 is thicker than the selective growth mask layer 13 in the Hall element 10 of a second modification illustrated in FIG. 4B. These are the differences from the Hall element 10 of the first embodiment in which the thickness of the contact layer 14 is the same as the thickness of the selective growth mask layer 13. The other components of the Hall element 10 of the first and second modifications are similar to those of the Hall element 10 of the first embodiment, and the corresponding constituent parts will be indicated by common reference signs. The thicknesses of the contact layer 14 and the selective growth mask layer 13 can be easily adjusted in the process of growing the crystal of the contact layer 14 illustrated in FIG. 3D and the process of forming the selective growth mask layer 13 illustrated in FIG. 3C in the manufacturing method of the first embodiment.

The contact layer 14 is thinner than the selective growth mask layer 13 in the Hall element 10 of the first modification illustrated in FIG. 4A. Therefore, at the boundary of the contact layer 14 and the selective growth mask layer 13, the surface of the contact layer 14 forms an inclined surface inclined toward the surface of the selective growth mask layer 13. In other words, the outer circumference of the contact layer 14 gradually rises toward the side opposite the substrate 11 in plan view illustrated in FIG. 1. The contact layer 14 of the first modification is thin, and this can shorten the time taken to form the contact layer 14 by the crystal growth. In addition, the number of crystal defects is reduced, and the lifetime of the contact layer 14 can be extended.

The contact layer 14 is thicker than the selective growth mask layer 13 in the Hall element 10 of the second modification illustrated in FIG. 4B. Therefore, the part of the contact layer 14 protruding upward from the opening formed in the selective growth mask layer 13 along the surface of the selective growth mask layer 13 and also extending outside from the opening is inclined toward the surface of the selective growth mask layer 13. In other words, the outer circumference of the contact layer 14 goes down toward the substrate 11 in plan view illustrated in FIG. 1. The area in contact with the metal electrode layers 15 increases in the contact layer 14 of the second modification, and this can reduce the contact resistance between the contact layer 14 and the metal electrode layers 15.

The contact layer 14 is thinner than the selective growth mask layer 13 in the example illustrated in the first modification, and the contact layer 14 is thicker than the selective growth mask layer 13 in the example illustrated in the second modification. However, whether the contact layer 14 is thin or thick in the examples may be based on the selective growth mask layer 13 with a predetermined thickness. In this case, the contact layer 14 is thinner than the selective growth mask layer 13 with the predetermined thickness in the first modification. The contact layer 14 is thicker than the selective growth mask layer 13 in the second modification. The contact layer 14 of the first modification is thinner than the contact layer 14 of the second modification.

### Second Embodiment

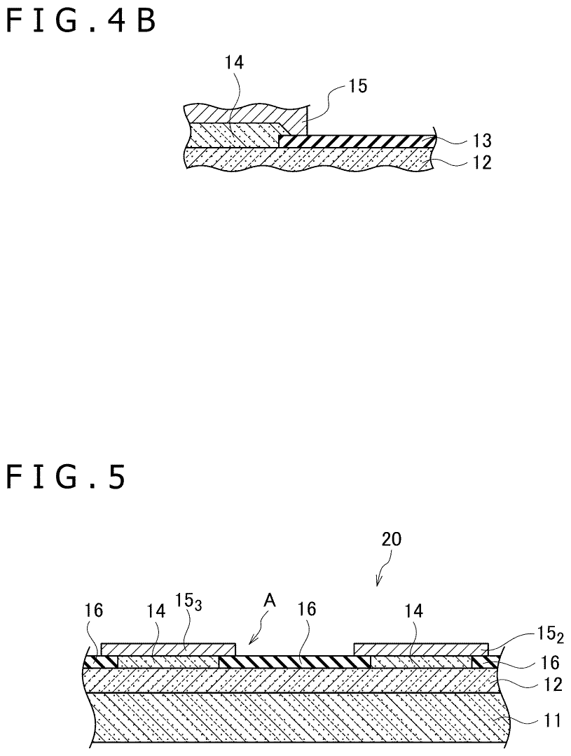

FIG. 5 is a cross-sectional view illustrating a Hall element 20 of a second embodiment. The Hall element 20 of the second embodiment is different from the Hall element 10 of the first embodiment in that a selective growth mask layer 16 containing SiN (silicon nitride) is used in place of the selective growth mask layer 13 containing SiO₂ (silicon dioxide) in the Hall element 10 of the first embodiment. The other components are similar to those of the Hall element 10 of the first embodiment, and the same reference signs are provided to the constituent elements in common with the Hall element 10 of the first embodiment to clarify the correspondence.

The Hall element 20 of the second embodiment is also manufactured by the series of processes of the manufacturing method illustrated in FIGS. 3A to 3G as with the Hall element 10 of the first embodiment. More specifically, in the process illustrated in FIG. 3C, SiN is deposited as the selective growth mask layer 16 on the top surface of the substrate 11 in place of SiO₂ of the selective growth mask layer 13. In the process illustrated in FIG. 3D, the selective growth mask layer 16 containing SiN is etched. In the process illustrated in FIG. 3E, the contact layer 14 is selectively grown in the openings of the selective growth mask layer 16.

As in the Hall element 10 of the first embodiment, the contact layer 14 in the Hall element 20 of the second embodiment is also formed by selectively growing the crystal on the magnetic sensitive layer 12 exposed in the openings formed in the selective growth mask layer 16. The selective growth mask layer 16 can be used to easily form the contact layer 14 in a desirable pattern and a desirable thickness, at the position on the magnetic sensitive layer 12 just below the metal electrode layers 15. The selective growth mask layer 16 contains SiN, and the selective growth mask layer 16 plays a role of protecting the covered top surface of the substrate 11 and the magnetic sensitive layer 12.

In the Hall element 20 of the second embodiment, Te is also used as impurities added in high concentration to the contact layer 14. Therefore, Te in high concentration can provide the carrier in high concentration to reduce the contact resistance between the contact layer 14 and the metal electrode layers 15. The reduction in the contact resistance can improve the sensitivity or the efficiency of the Hall element 20. Although the contact layer 14 is in contact with the magnetic sensitive layer 12, Te in high concentration contained in the contact layer 14 has a property of being likely to be diffused. Therefore, the degradation of the magnetic sensitive layer 12, such as reduction in the mobility caused by the diffusion of Te to the magnetic sensitive layer 12, does not occur, and the sensitivity of the Hall element 20 is secured.

In the Hall element 20 of the second embodiment, the selective growth mask layer 16 contains SiN that functions as an excellent barrier for the impurity diffusion. Therefore, the resistance to moisture or metal contamination is secured in the Hall element 20 of the second embodiment.

Note that, in the second embodiment, the contact layer 14 can also be thinner than the selective growth mask layer 16 as illustrated in the first modification of FIG. 4, or the contact layer 14 can also be thicker than the selective growth mask layer 16 as illustrated in the second modification of FIG. 4B. When the contact layer 14 is thinner than the selective growth mask layer 16 as in FIG. 4A, the time taken to form the contact layer 14 by the crystal growth can be shortened. The number of crystal defects can be reduced, and the lifetime of the contact layer 14 can be extended. This is similar to the first embodiment. When the contact layer 14 is thicker than the selective growth mask layer 16 as in FIG. 4B, the area in contact with the metal electrode layers 15 increases. Therefore, the contact resistance between the contact layer 14 and the metal electrode layers 15 can be reduced. This is also similar to the first embodiment.

### Third Embodiment

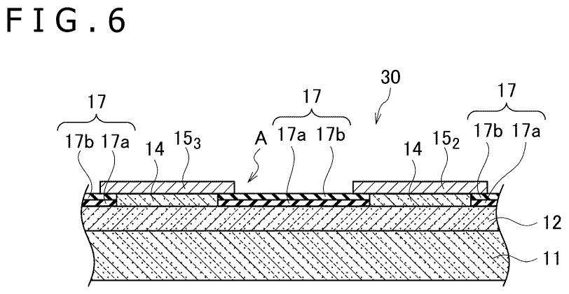

FIG. 6 is a cross-sectional view illustrating a Hall element 30 of a third embodiment. The Hall element 30 of the third embodiment is different from the Hall element 10 of the first embodiment in that a selective growth mask layer 17 based on a laminated body including a first layer 17a containing SiO₂ and a second layer 17b containing SiN (silicon nitride) is used in place of the selective growth mask layer 13 including a single layer of SiO₂ (silicon dioxide) in the Hall element 10 of the first embodiment. The other components are similar to those of the Hall element 10 of the first embodiment, and the same reference signs are provided to the constituent elements in common with the Hall element 10 of the first embodiment to clarify the correspondence.

The Hall element 30 of the third embodiment is also manufactured by the series of processes of the manufacturing method illustrated in FIGS. 3A to 3G as with the Hall element 10 of the first embodiment. More specifically, in the process illustrated in FIG. 3C, the laminated body including the first layer 17a of SiO₂ and the second layer 17b of SiN is deposited as the selective growth mask layer 17 on the top surface of the substrate 11 in place of SiO₂ of the selective growth mask layer 13. In the process illustrated in FIG. 3D, the selective growth mask layer 17 based on the laminated body is etched. In the process illustrated in FIG. 3E, the contact layer 14 is selectively grown in the openings of the selective growth mask layer 17.

In the Hall element 23 of the third embodiment, the contact layer 14 is also formed by selectively growing the crystal on the magnetic sensitive layer 12 exposed in the openings formed in the selective growth mask layer 17 as in the Hall element 10 of the first embodiment. The selective growth mask layer 17 can be used to easily form the contact layer 14 in a desirable pattern and a desirable thickness, at the position on the magnetic sensitive layer 12 just below the metal electrode layers 15. The selective growth mask layer 17 includes the laminated body including the first layer 17a of SiO₂ and the second layer 17b of SiN. Therefore, the selective growth mask layer 17 plays a role of protecting the covered top surface of the substrate 11 and the magnetic sensitive layer 12.

In the Hall element 30 of the third embodiment, Te is also used as impurities added in high concentration to the contact layer 14. Therefore, Te in high concentration can provide the carrier in high concentration to reduce the contact resistance between the contact layer 14 and the metal electrode layers 15. The reduction in the contact resistance can improve the sensitivity or the efficiency of the Hall element 30. Although the contact layer 14 is in contact with the magnetic sensitive layer 12, Te in high concentration contained in the contact layer 14 has a property of being likely to be diffused. Therefore, the degradation of the magnetic sensitive layer 12, such as reduction in the mobility caused by the diffusion of Te to the magnetic sensitive layer 12, does not occur, and the sensitivity of the Hall element 30 is secured.

In the Hall element 30 of the third embodiment, the first layer 17a of the selective growth mask layer 17 contains SiO₂ that is more excellent in adhesion to GaAs than SiN, and the second layer 17b as the outermost layer contains SiN that functions as an excellent barrier for the impurity diffusion. Therefore, the adhesion of the selective growth mask layer 17 and the magnetic sensitive layer 12 containing n-type GaAs is secured, and the resistance to moisture or metal contamination is secured in the Hall element 30 of the third embodiment.

Note that, in the third embodiment, the contact layer 14 can also be thinner than the selectively growth mask layer 17 as illustrated in the first modification of FIG. 4A, or the contact layer 14 can also be thicker than the selective growth mask layer 17 as illustrated in the second modification of FIG. 4B. When the contact layer 14 is thinner than the selective growth mask layer 17 as in FIG. 4A, the time taken to form the contact layer 14 by the crystal growth can be shortened. The number of crystal defects can be reduced, and the lifetime of the contact layer 14 can be extended. This is similar to the first embodiment. When the contact layer 14 is thicker than the selective growth mask layer 17 as in FIG. 4B, the area in contact with the metal electrode layers 15 increases. Therefore, the contact resistance between the contact layer 14 and the metal electrode layers 15 can be reduced. This is also similar to the first embodiment.

Although the selective growth mask layer 17 is the laminated body including the first layer 17a containing SiO₂ and the second layer 17b containing SiN in the third embodiment, the order of laminated layers is not limited to this. The selective growth mask layer 17 may include a laminated body including a first layer of SiN and a second layer of SiO₂.

### Supplement 1

The Hall element 10 includes the substrate 11 including a compound semiconductor; the magnetic sensitive layer 12 formed in a substantially cross-shaped pattern in plan view on the top surface of the substrate 11; the selective growth mask layer 13 formed on the top surface to cover the magnetic sensitive layer 12 such that predetermined areas at the ends of the substantially cross-shaped pattern of the magnetic sensitive layer 12 are exposed; the contact layer 14 formed on the magnetic sensitive layer 12 exposed from the selective growth mask layer 13, the contact resistance to metal of the contact layer 14 being lower than the contact resistance to metal of the magnetic sensitive layer 12; and the metal electrode layer 15 formed in a predetermined pattern on the selective growth mask layer 13 and the contact layer 14 in such a manner as to cover at least the contact layer 14, in which each of the magnetic sensitive layer 12 and the contact layer 14 includes the compound semiconductor. The contact layer 14 can reduce the contact resistance between the contact layer 14 and the metal electrode layer 15, and the sensitivity or the efficiency of the Hall element can be improved. The selective growth mask layer 13 can cover and protect the magnetic sensitive layer 12 and the top surface of the substrate 11.

### Supplement 2

The compound semiconductor according to supplement 1 may include a III-V semiconductor. The compound semiconductor can be appropriately selected from the III-V semiconductors.

### Supplement 3

The III-V semiconductor according to supplement 2 may contain at least one of GaAs, InSb, and InAs. The III-V semiconductor can be appropriately selected from GaAs, InSb, and InAs.

### Supplement 4

At least one of Si and Te may be added to the magnetic sensitive layer 12 according to any one of supplements 1 to 3. An n-type semiconductor can be provided by adding at least one of Si and Te. Te has a property of being likely to be diffused. Therefore, the sensitivity of the Hall element 10 is not reduced by diffusion of Te to the magnetic sensitive layer 12.

### Supplement 5

The selective growth mask layer 13 according to any one of supplements 1 to 4 may contain SiO₂. The selective growth mask layer 13 contains SiO₂. Therefore, the crystal growth on the selective growth mask layer 13 can be inhibited, and the crystal can be selectively grown in the areas not covered by the selective growth mask layer 13. The selective growth mask layer 13 contains SiO₂, and the magnetic sensitive layer 12 and the top surface of the substrate 11 covered by the selective growth mask layer 13 can be protected.

### Supplement 6

The selective growth mask layer 16 according to any one of supplements 1 to 4 may contain SiN. The selective growth mask layer 16 contains SiN. Therefore, the crystal growth on the selective growth mask layer 16 can be inhibited, and the crystal can be selectively grown in the areas not covered by the selective growth mask layer 16. The selective growth mask layer 16 contains SiN, and the magnetic sensitive layer 12 and the top surface of the substrate 11 covered by the selective growth mask layer 16 can be protected.

### Supplement 7

The selective growth mask layer 17 according to any one of supplements 1 to 4 may include a laminated body containing sequentially laminated SiO₂ and SiN. The selective growth mask layer 17 includes the laminated body of SiO₂ and SiN. Therefore, the crystal growth on the selective growth mask layer 17 can be inhibited, and the crystal can be selectively grown in the areas not covered by the selective growth mask layer 17. The selective growth mask layer 17 includes the laminated body of SiO₂ and SiN, and the magnetic sensitive layer 12 and the top surface of the substrate 11 covered by the selective growth mask layer 17 can be protected.

### Supplement 8

Te may be added to the contact layer according to any one of supplements 1 to 7. An n-type semiconductor can be provided by adding Te. Te has a property of being likely to be diffused. Therefore, the sensitivity of the Hall element 10 is not reduced by diffusion of Te to the magnetic sensitive layer 12.

### Supplement 9

The contact layer 14 according to any one of supplements 1 to 8 may be thinner than the selective growth mask layer 13. The time taken to form the contact layer 14 is shortened, and the number of crystal defects is reduced.

### Supplement 10

The contact layer 14 according to any one of supplements 1 to 8 may be thicker than the selective growth mask layer 13. The contact area of the metal electrode layer 15 and the contact layer 14 can be increased, and the contact resistance can be reduced.

### Supplement 11

The manufacturing method of the Hall element 10 includes the process of forming the magnetic sensitive layer 12 in a substantially cross-shaped pattern in plan view on the top surface of the substrate 11 including a compound semiconductor; the process of forming the selective growth mask layer 13 on the top surface to cover the magnetic sensitive layer 12 such that predetermined areas at the ends of the substantially cross-shaped pattern of the magnetic sensitive layer 12 are exposed; the process of selectively growing the contact layer 14 on the magnetic sensitive layer 12 exposed from the selective growth mask layer 13, the contact resistance to metal of the contact layer 14 being lower than the contact resistance to metal of the magnetic sensitive layer 12; and the process of forming the metal electrode layer 15 in a predetermined pattern on the selective growth mask layer 13 and the contact layer 14 in such a manner as to cover at least the contact layer 14, in which each of the magnetic sensitive layer 12 and the contact layer 14 includes the compound semiconductor. The contact layer 14 can reduce the contact resistance between the contact layer 14 and the metal electrode layer 15, and the sensitivity or the efficiency of the Hall element can be improved. The selective growth mask layer 13 can be used to easily form the contact layer 14 on the magnetic sensitive layer 12 in a desirable pattern and a desirable thickness.

### Supplement 12

The compound semiconductor according to supplement 11 may include a III-V semiconductor. The compound semiconductor can be appropriately selected from the III-V semiconductors.

### Supplement 13

The III-V semiconductor according to supplement 12 may contain at least one of GaAs, InSb, and InAs. The III-V semiconductor can be appropriately selected from GaAs, InSb, and InAs.

### Supplement 14

At least one of Si and Te may be added to the magnetic sensitive layer 12 according to any one of supplements 11 to 13. An n-type semiconductor can be provided by adding at least one of Si and Te. Te has a property of being likely to be diffused. Therefore, the sensitivity of the Hall element 10 is not reduced by diffusion of Te to the magnetic sensitive layer 12.

### Supplement 15

Te may be added to the contact layer 14 according to any one of supplements 11 to 14. An n-type semiconductor can be provided by adding Te. Te has a property of being likely to be diffused. Therefore, the sensitivity of the Hall element 10 is not reduced by diffusion of Te to the magnetic sensitive layer 12.

### Supplement 16

The selective growth mask layer 13 according to any one of supplements 11 to 15 may contain SiO₂. The selective growth mask layer 13 can inhibit the crystal growth on the selective growth mask layer 13, and the crystal can be selectively grown in the areas not covered by the selective growth mask layer 13. The selective growth mask layer 13 can protect the magnetic sensitive layer 12 and the top surface of the substrate 11 covered by the selective growth mask layer 13.

### Supplement 17

The selective growth mask layer 16 according to any one of supplements 11 to 15 may contain SiN. The selective growth mask layer 16 can inhibit the crystal growth on the selective growth mask layer 16, and the crystal can be selectively grown in the areas not covered by the selective growth mask layer 16. The selective growth mask layer 16 can protect the magnetic sensitive layer 12 and the top surface of the substrate 11 covered by the selective growth mask layer 16.

### Supplement 18

The selective growth mask layer 17 according to any one of supplements 11 to 15 may include a laminated body containing sequentially laminated SiO₂ and SiN. The selective growth mask layer 17 can inhibit the crystal growth on the selective growth mask layer 17, and the crystal can be selectively grown in the areas not covered by the selective growth mask layer 17. The selective growth mask layer 17 can protect the magnetic sensitive layer 12 and the top surface of the substrate 11 covered by the selective growth mask layer 17.

### Supplement 19

The process of forming the magnetic sensitive layer 12 according to any one of supplements 11 to 18 may further include: the process of forming the magnetic sensitive layer 12 in such a manner as to cover the top surface of the substrate 11; and the process of forming the magnetic sensitive layer 12 in a substantially cross-shaped pattern in plan view. The magnetic sensitive layer 12 is formed in a pattern suitable for the Hall element.

### Supplement 20

The process of forming the selective growth mask layer 13 according to any one of supplements 11 to 19 may further include: the process of forming the selective growth mask layer 13 in such a manner as to cover the magnetic sensitive layer 12; and the process of forming the selective growth mask layer 13 in a predetermined pattern. The selective growth mask layer 13 is removed in the areas for the selective crystal growth, and the openings are formed.

### Supplement 21

The process of forming the metal electrode layer 15 according to any one of supplements 11 to 20 may further include: the process of forming the metal electrode layer 15 in such a manner as to cover the selective growth mask layer 13 and the contact layer 14; and the process of forming the metal electrode layer 15 in a predetermined pattern. Each metal electrode layer 15 is connected to each contact layer 14, and each metal electrode layer 15 forms an electrically independent electrode.

According to an embodiment of the present disclosure, the contact resistance between the magnetic sensitive layer and the metal electrode layer can be reduced.

It should be understood by those skilled in the art that various modifications, combinations, sub-combinations and alterations may occur depending on design requirements and other factors insofar as they are within the scope of the appended claims or the equivalents thereof.

What is claimed is:

1. A magnetoelectric conversion element comprising:
a substrate including a compound semiconductor;
a magnetic sensitive layer formed in a predetermined pattern on a top surface of the substrate;
a selective growth mask layer formed on the top surface to cover the magnetic sensitive layer such that the magnetic sensitive layer is exposed in a predetermined pattern;
a contact layer formed on the magnetic sensitive layer exposed from the selective growth mask layer, a contact resistance to metal of the contact layer being lower than a contact resistance to metal of the magnetic sensitive layer; and
a metal electrode layer formed in a predetermined pattern on the selective growth mask layer and the contact layer in such a manner as to cover at least the contact layer, wherein
each of the magnetic sensitive layer and the contact layer includes the compound semiconductor.

2. The magnetoelectric conversion element according to claim 1, wherein
the compound semiconductor includes a III-V semiconductor.

3. The magnetoelectric conversion element according to claim 2, wherein
the III-V semiconductor includes at least one of gallium arsenide, indium antimonide, and indium arsenide.

4. The magnetoelectric conversion element according to claim 1, wherein
at least one of silicon and tellurium is added to the magnetic sensitive layer.

5. The magnetoelectric conversion element according to claim 1, wherein
the selective growth mask layer includes silicon dioxide.

6. The magnetoelectric conversion element according to claim 1, wherein
the selective growth mask layer includes silicon nitride.

7. The magnetoelectric conversion element according to claim 1, wherein
the selective growth mask layer includes a laminated body containing sequentially laminated silicon dioxide and silicon nitride.

8. The magnetoelectric conversion element according to claim 1, wherein
tellurium is added to the contact layer.

9. The magnetoelectric conversion element according to claim 1, wherein
the contact layer is thinner than the selective growth mask layer.

10. The magnetoelectric conversion element according to claim 1, wherein
the contact layer is thicker than the selective growth mask layer.

11. A manufacturing method of a magnetoelectric conversion element, the manufacturing method comprising:
forming a magnetic sensitive layer in a predetermined pattern on a top surface of a substrate including a compound semiconductor;
forming a selective growth mask layer on the top surface to cover the magnetic sensitive layer such that the magnetic sensitive layer is exposed in a predetermined pattern;
selectively growing a contact layer on the magnetic sensitive layer exposed from the selective growth mask layer, a contact resistance to metal of the contact layer being lower than a contact resistance to metal of the magnetic sensitive layer; and
forming a metal electrode layer in a predetermined pattern on the selective growth mask layer and the contact layer in such a manner as to cover at least the contact layer, wherein
each of the magnetic sensitive layer and the contact layer includes the compound semiconductor.

12. The manufacturing method of the magnetoelectric conversion element according to claim 11, wherein
the compound semiconductor includes a III-V semiconductor.

13. The manufacturing method of the magnetoelectric conversion element according to claim 12, wherein
the III-V semiconductor includes at least one of gallium arsenide, indium antimonide, and indium arsenide.

14. The manufacturing method of the magnetoelectric conversion element according to claim 11, wherein
at least one of silicon and tellurium is added to the magnetic sensitive layer.

15. The manufacturing method of the magnetoelectric conversion element according to claim 11, wherein
tellurium is added to the contact layer.

16. The manufacturing method of the magnetoelectric conversion element according to claim 11, wherein
the selective growth mask layer includes silicon dioxide.

17. The manufacturing method of the magnetoelectric conversion element according to claim 11, wherein
the selective growth mask layer includes silicon nitride.

18. The manufacturing method of the magnetoelectric conversion element according to claim 11, wherein
the selective growth mask layer includes a laminated body containing sequentially laminated silicon dioxide and silicon nitride.

19. The manufacturing method of the magnetoelectric conversion element according to claim 11, wherein
forming the magnetic sensitive layer further includes
forming the magnetic sensitive layer in such a manner as to cover the top surface, and
forming the magnetic sensitive layer in a predetermined pattern.

20. The manufacturing method of the magnetoelectric conversion element according to claim 11, wherein
forming the selective growth mask layer further includes
forming the selective growth mask layer in such a manner as to cover the magnetic sensitive layer, and
forming the selective growth mask layer in a predetermined pattern.

21. The manufacturing method of the magnetoelectric conversion element according to claim 11, wherein
forming the metal electrode layer further includes
forming the metal electrode layer in such a manner as to cover the selective growth mask layer and the contact layer, and
forming the metal electrode layer in a predetermined pattern.
